(19) United States
(12) Patent Application Publication
(10) Pub. No.: US 2026/0128691 A1
(43) Pub. Date: May 7, 2026

(54) BRAKE CONTROL METHOD, DEVICE, MODE CONTROL DEVICE AND COMPUTER READABLE MEDIUM

(71) Applicant: JIANGSU DONGCHENG TOOLS TECHNOLOGY CO., LTD, Nantong (CN)

(72) Inventors: Minming LIU, Nantong (CN); Jiawei CHEN, Nantong (CN)

(21) Appl. No.: 18/858,438

(22) PCT Filed: Oct. 27, 2023
(86) PCT No.: PCT/CN2023/127039

§ 371 Date: Oct. 21, 2024

(30) Foreign Application Priority Data
Oct. 31, 2022 (CN) 202211365685.0

(51) Int. Cl. H02P 6/24; G01R 15/04; G01R 19/165; H02P 6/08

(52) U.S. Cl. CPC H02P 6/24; G01R 15/04; G01R 19/16538; H02P 6/085; H02P 2207/05

(57) ABSTRACT

The present application discloses a brake control method, a brake control device and a computer readable medium. The control method includes following steps: collecting a voltage value of a voltage-dividing resistor R₁₂; calculating a first bus voltage value according to the voltage value of the voltage-dividing resistor R₁₂; detecting a change of a bus voltage within a first time interval and calculating a voltage change rate; estimating a second bus voltage value within a second time interval according to the voltage change rate, the second bus voltage value being an estimated bus voltage value; determining a magnitude relationship between the estimated bus voltage value and a preset value; in response that the estimated bus voltage value is greater than the preset value, stopping a slow braking; in response that the estimated bus voltage value is less than the preset value, continuing to performing the slow braking.

### FIELD

The present application relates to a field of electrical tools, and more specifically, to a braking control method, a control device and a computer-readable medium.

### BACKGROUND

In handheld power tools such as electric wrenches and electric circular saws, when stopping, if a direct brake method is used, the direct brake method will cause a brushless motor to instantly generate a huge braking torque, resulting in a large reaction force of the tool, making the user feel poor and noisy; if a slow brake method is used, the slow brake method will reduce the reaction force and the noise of the tool, but repeatedly turning switch tubes on and off will cause current backflow and cause excessive voltage, thereby damaging MOS tubes and affecting a service life of the power tool.

Please refer to a Chinese utility model patent issued No. CN213342062U published on Jun. 1, 2021, which discloses that when a switch is disconnected, at least two upper switch tubes or at least two lower switch tubes of an inverter circuit are controlled to be turned on at a first duty cycle less than 100% for braking. When the voltage detected by a peak voltage detection module is higher than a preset value stored in a control module, the control module controls at least two upper switch tubes or at least two lower switch tubes to be turned on at a second duty cycle of 100% for braking. Although it controls a peak voltage generated by an early braking, it does not control a forced power generated by a later braking, which will still generate a lot of noise and make the user feel poor.

Therefore, it is necessary to design a brushless direct current (DC) motor braking device and method to solve the above problems.

### SUMMARY

In view of deficiencies in the prior art, a purpose of the present application is to provide a brushless DC motor braking device and method to solve the problems of voltage increase during braking, which may cause damage to electronic components, and to avoid the problems of excessive braking torque, unstable braking transition, and poor user experiment.

The present application solves existing technical problems by adopting following technical solutions: a brake control method, comprising:
S1: collecting a voltage value of a voltage-dividing resistor R12;
S2: calculating a first bus voltage value according to the voltage value of the voltage-dividing resistor R12;
S3: detecting a change of a bus voltage within a first time interval and calculating a voltage change rate;
S4: estimating a second bus voltage value within a second time interval according to the voltage change rate, the second bus voltage value being an estimated bus voltage value;
S5: determining a magnitude relationship between the estimated bus voltage value and a preset value; in response that the estimated bus voltage value is greater than the preset value, stopping a slow braking; in response that the estimated bus voltage value is less than the preset value, performing the slow braking.

A further improved solution includes: performing the slow braking comprises performing the slow braking according to a modulation signal with a pulse width modulation (PWM) duty cycle of upper three tubes being 0, and with a PWM duty cycle of lower three tubes, and the PWM duty cycle of lower three tubes having a PWM initial duty cycle and gradually increasing.

In a further improved solution, the initial duty cycle is 5 %-50%, and when performing the slow braking, the duty cycle is less than 100%.

In a further improved solution, the bus voltage value Uₜₒₜₐₗ is calculated according to a formula of Uₜₒₜₐₗ=(R₆+R₁₂)÷R₁₂×U_{ad}, Uad is the voltage value of R12, and R6 is another voltage-dividing resistor.

In a further improved solution, the voltage change rate is a slope, which is calculated according to a formula of K=(Uₜₒₜₐₗ₂−Uₜₒₜₐₗ₁)÷T, K is the slope, and T is a time interval for the voltage value of R12 to change from Uₜₒₜₐₗ₁ to Uₜₒₜₐₗ₂, Uₜₒₜₐₗ₁ and Uₜₒₜₐₗ₂ are voltage values of R12.

A further improved solution includes: in response that the estimated bus voltage value is greater than the preset value, outputting a PWM modulation signal with a PWM duty cycle of upper three tubes is 0 and a PWM duty cycle of lower three tubes is 0.

A further improved solution includes a brake control device, and the brake control device includes:
a voltage collecting module, configured to collect a voltage value of a voltage-dividing resistor R12;
a first calculation module, configured to calculate a first bus voltage value according to the voltage value of the voltage-dividing resistor R12;
a detecting module, configured to detect a change of a bus voltage within a first time interval and calculate a voltage change rate;
a second calculation module, configured to estimate a second bus voltage value within a second time interval according to the voltage change rate, the second bus voltage value being an estimated bus voltage value;
a determining module, configured to determine a magnitude relationship between the estimated bus voltage value and a preset value; stop a slow braking in response that the estimated bus voltage value is greater than the preset value; and perform the slow braking in response that the estimated bus voltage value is less than the preset value.

A further improved solution includes a brake control device, and the brake control device includes:
a voltage collecting circuit, configured to collect a voltage value of a voltage-dividing resistor R12;
a MCU, configured to calculate a first bus voltage value according to the voltage value of the voltage-dividing resistor R12; detect a change of a bus voltage within a first time interval and calculate a voltage change rate; estimate a second bus voltage value; determine a magnitude relationship between the estimated bus voltage value and a preset value, and stop a slow braking in response that the estimated bus voltage value is greater than the preset value, and perform the slow braking in response that the estimated bus voltage value is less than the preset value.

A further improved solution includes a mode control device, and the mode control device includes a memory and a processor, and the memory stores a computer program that can be run on the processor.

A further improved solution includes a computer readable medium having a non-volatile program code executable by a processor.

Compared with the prior art, the present application has following beneficial effects: when a brake signal is detected, the MOS tube brakes with an initial duty cycle of 5%-50%, the duty cycle gradually increases at a fixed slope and the duty cycle is always maintained below 100% of the modulation signal; the detection module detects the voltage value of the voltage-dividing resistor in real time and sends the value to the calculation module to calculate and estimate the bus voltage value for the next time interval; when the estimated bus voltage value is greater than the preset value stored inside a power tool, the duty cycles of the six MOS tubes are all 0, and the braking stops until the estimated bus voltage value is lower than the preset value, and the power tool starts braking again. By ending the braking early, the MOS tubes can be prevented from being damaged due to excessive voltage, thereby extending the service life of the power tool, at the same time, excessive braking torque can be avoided, making the braking smoother and improving the user's experiment.

### BRIEF DESCRIPTION OF THE DRAWINGS

The specific embodiments of the present application are further described in detail below in conjunction with the accompanying drawings.

FIG. 1 is a circuit diagram of a brushless DC motor braking system according to the present application.

FIG. 2 is a module diagram of the brushless DC motor braking system of the present application.

FIG. 3 is a schematic diagram showing a comparison of bus voltage and PWM modulation signal waveforms of the brushless DC motor braking system of the present application during braking.

FIG. 4 is a flow chart of a brushless DC motor braking system according to the present application.

### REFERENCE NUMBER

1: power module; 2: voltage sampling module; 3: motor drive module; 4: motor; 5: MCU.

### DETAILED DESCRIPTION

The present application is further described in detail below in conjunction with the accompanying drawings and implementation modes.

The brake control method and device described in the present application are suitable for intelligent device such as power tools/power device, and the power tools/power device can be garden tools, handheld tools, or other automated equipment with a slow braking function; as long as the above-mentioned equipment/tools can adopt an essential content of the technical solution disclosed below, they can fall within a protection scope of the present application.

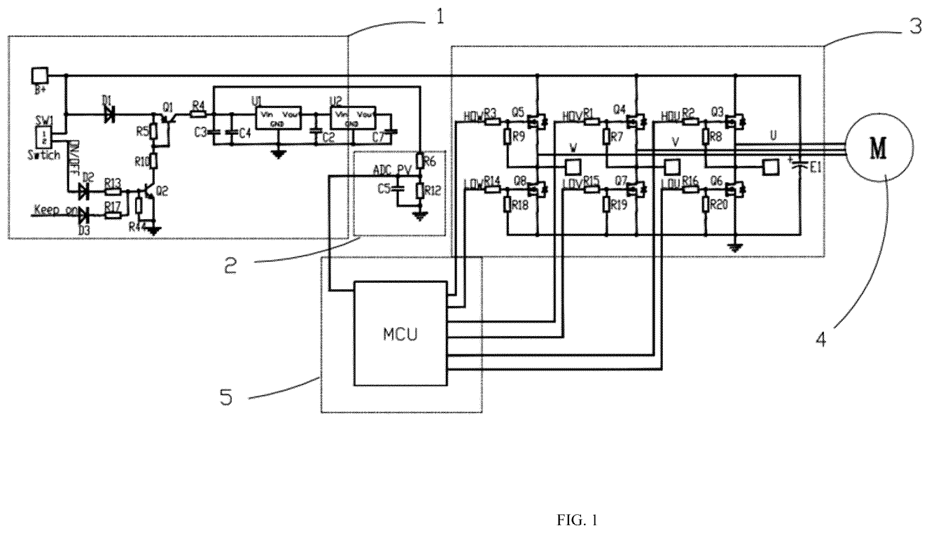

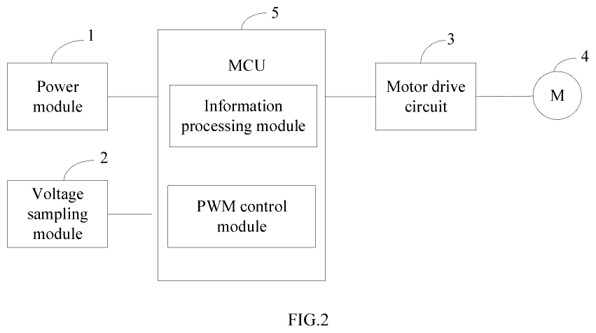

Referring to FIG. 1 and FIG. 2, a brushless DC motor brake device includes a power module 1, a voltage sampling module 2, a brushless DC motor 4, a microcontroller (MCU) 5 and a motor drive circuit 3. A power module is electrically connected to a motor drive circuit, and the motor drive module is electrically connected to the brushless DC motor 4 to control an operation of the brushless DC motor. The voltage sampling module is electrically connected to the MCU, and is used to transmit a collected voltage value of a voltage-dividing resistor to the MCU. The MCU includes an information processing module and a Pulse width modulation (PWM) control module (as shown in FIG. 2). The information processing module is used to calculate a bus voltage value by a received voltage-dividing resistor value, and calculate a bus voltage change rate (that is the slope) within a time interval, calculate a change value of the bus voltage in the next time interval according to the slope, and determine an estimated bus voltage value according to the change value. The MCU internally stores preset values, that is, a bus high threshold value and a bus low threshold value. When the estimated bus voltage value reaches the bus high threshold value, the PWM control module controls to output a PWM modulation signal with the duty cycle of upper three tubes being 0 and the duty cycle of lower three tubes being 0, and suspends a brake, and when the estimated bus voltage value reaches the bus low threshold value, the PWM control module controls to output the PWM modulation signal with the duty cycle of the upper three tubes being 0, and with the PWM duty cycle of the lower three tubes having an initial duty cycle and increasing slowly with a fixed slope from the initial duty cycle, starts braking and continue braking until shutdown. In one embodiment, the bus high threshold value is a withstand voltage value of the bus voltage. Once the withstand voltage value is exceeded, it is easy to cause damage to the MOS tube and the circuit, affecting a service life of the power tools. The bus low threshold value is a minimum threshold to ensure the braking efficiency when the brushless DC motor brakes. If it is lower than the threshold, it is easy to cause a braking time interval to be prolonged, the braking efficiency to be reduced, affecting an operating experience.

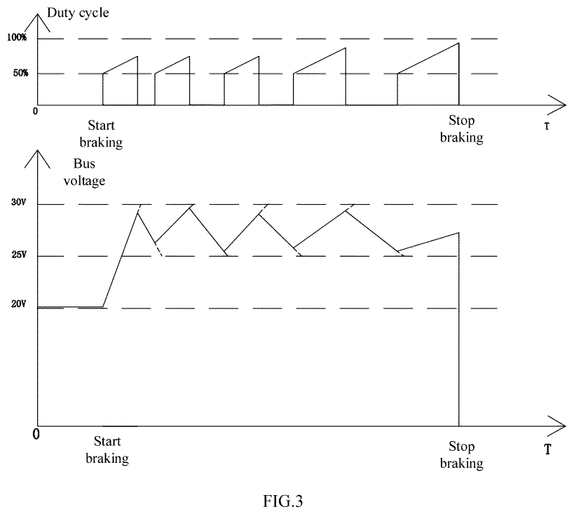

Referring to FIG. 3, a reference value of the bus high threshold value is 30V, a reference value of the bus low threshold value is 25V, and the initial duty cycle is 5%-50%, preferably 50%. The voltage sampling module transmits the collected voltage value to the information processing module. The information processing module is used to calculate the bus voltage value by the received voltage-dividing resistance value, and calculate the bus voltage change rate within a time interval, that is, the slope. According to the slope, the change value of the bus voltage in the next time interval is calculated, and the estimated bus voltage value is determined according to the change value. When the estimated bus voltage value reaches the bus high threshold value, that is, 30V, the PWM control module in the MCU controls the output of the modulation signal with the duty cycle of the upper and lower switch tubes being 0, controls the brake to stop, and continues to detect until the estimated bus voltage value reaches the low high threshold value, that is, 25V. When the estimated bus voltage value reaches the bus low threshold value, the PWM control module controls the output of the modulation signal with the PWM duty cycle of the upper three tubes being 0, and the PWM duty cycle of the lower three tubes having an initial duty cycle of 50 % and gradually increasing at a fixed slope, and the duty cycle is always lower than 100%.

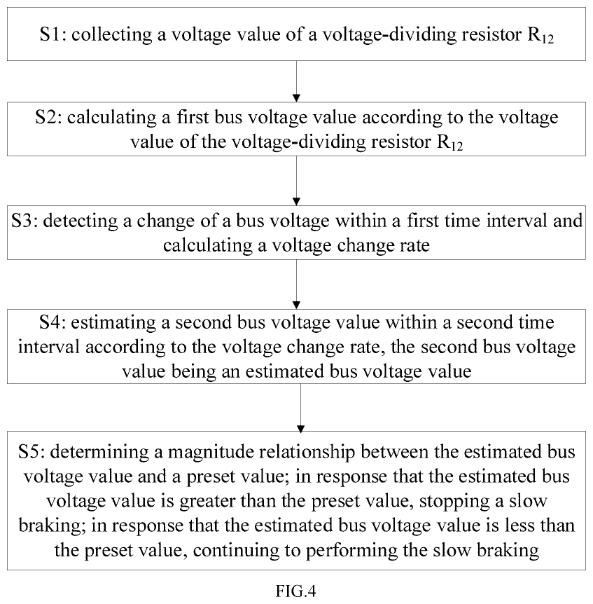

Referring to FIG. 4, the present application further provides a brushless DC motor brake method, which is implemented by the above-mentioned control device, and the method includes following steps. S1: a voltage collecting module collects a voltage value of a voltage-dividing resistor R12; S2: the MCU calculates the first bus voltage value according to the voltage value of the voltage-dividing resistor R12 by a calculation formula, and the calculation formula of the bus voltage value Uₜₒₜₐₗ is: Uₜₒₜₐₗ=(R₆+R₁₂)÷R₁₂×U_{ad}, Uad is the voltage value across R12, and R6 is another voltage-dividing resistor; S3: the MCU detects a change of the bus voltage in a first time interval and calculates the voltage change rate, that is, the slope K, and the calculation formula of the slope K is: K=(Uₜₒₜₐₗ₂−Uₜₒₜₐₗ₁)÷T, where T is the time interval when the voltage value at both ends of R12 changes from Uₜₒₜₐₗ₁ to Uₜₒₜₐₗ₂; S4: the change value of the bus voltage in the next time interval is calculated according to the slope, and the estimated bus voltage value is determined according to the change value; S5: a magnitude relationship between the estimated bus voltage value and the preset value is determined, and the preset value includes the bus high threshold value and the bus low threshold value; when the estimated bus voltage value is greater than the bus high threshold value, the PWM modulation signal with a PWM duty cycle of upper three tubes being 0 and a PWM duty cycle of the lower three tubes being 0 is output, and slow braking is stopped; when the estimated bus voltage value is less than the bus low threshold value, the PWM modulation signal with the PWM duty cycle of the upper three tubes being 0, and the PWM duty cycle of the lower three tubes having the initial duty cycle and increasing slowly from the initial duty cycle, is output, and slow braking is continued. In one embodiment, the duty cycle of the upper three tubes are 0, and the duty cycle of the lower three tubes have an initial duty cycle of 5%-50%, preferably 50%, and the duty cycle is always less than 100% during a gradual increase. In one embodiment, the bus high threshold value is the withstand voltage value of the bus voltage. Once the withstand voltage value is exceeded, it is easy to cause damage to the MOS tube and the circuit, affecting the service life of the power tool. The bus low threshold value is the minimum threshold to ensure the braking efficiency when the brushless DC motor brakes. If it is lower than the threshold, it is easy to cause the braking time interval to be prolonged, the braking efficiency to be reduced, affecting the operating experience.

The present application also provides a brake control device, and the above method is implemented by the brake control device. The brake control device can implement all the above methods. The brake control circuit includes: a voltage collecting circuit, collecting a voltage value of a voltage-dividing resistor R12; a MCU, calculating the first bus voltage value according to the voltage value of the voltage-dividing resistor R12 by the calculation formula, and the calculation formula of the bus voltage value Uₜₒₜₐₗ being: Uₜₒₜₐₗ=(R₆+R₁₂)÷R₁₂×U_{ad}, where Uad is the voltage value across R12, and R6 is another voltage-dividing resistor. The MCU further detects the change of the bus voltage in the first time interval and calculates the voltage change rate, that is, the slope K, and the calculation formula of the slope K is: K=(Uₜₒₜₐₗ₂−Uₜₒₜₐₗ₁)+T, T is the time interval when the voltage value at both ends of R12 changes from Uₜₒₜₐₗ₁ to Uₜₒₜₐₗ₂; calculates the change value of the bus voltage in the next time period according to the slope, and determines the estimated bus voltage value according to the change value; determines the magnitude relationship between the estimated bus voltage value and the preset value, and the preset value includes the bus high threshold value and the bus low threshold value. When the estimated bus voltage value is greater than the bus high threshold value, the PWM modulation signal with the PWM duty cycle of upper three tubes being 0 and the PWM duty cycle of the lower three tubes being 0 is output, and slow braking is stopped; when the estimated bus voltage value is less than the bus low threshold value, the PWM modulation signal with the PWM duty cycle of the upper three tubes being 0, and the PWM duty cycle of the lower three tubes having the initial duty cycle and increasing slowly from the initial duty cycle, is output, and slow braking is continued. In one embodiment, the duty cycle of the upper three tubes are 0, and the lower three tubes have an initial duty cycle of 5%-50%, preferably 50%, and the duty cycle is always less than 100% during a gradual increase. In one embodiment, the bus high threshold value is the withstand voltage value of the bus voltage. Once the withstand voltage value is exceeded, it is easy to cause damage to the MOS tube and the circuit, affecting the service life of the power tool. The bus low threshold value is the minimum threshold to ensure the braking efficiency when the brushless DC motor brakes. If it is lower than the threshold, it is easy to cause the braking time interval to be prolonged, the braking efficiency to be reduced, affecting the operating experience.

The present application also provides a brake control device, and the above method is implemented by the brake control device. The brake control device can implement all the above methods. The brake control circuit includes: the voltage collecting module, configured to collect a voltage value of a voltage-dividing resistor R12; a first calculation module, configured to calculate the first bus voltage value according to the voltage value of the voltage-dividing resistor R12 by the calculation formula, and the calculation formula of the bus voltage value Uₜₒₜₐₗ being: Uₜₒₜₐₗ=(R₆+R₁₂)÷R₁₂×U_{ad}, where Uad is the voltage value across R12, and R6 is another voltage-dividing resistor; a detecting module, configured to detect the change of the bus voltage in the first time interval and calculates the voltage change rate, that is, the slope K, and the calculation formula of the slope K being: K=(Uₜₒₜₐₗ₂−Uₜₒₜₐₗ₁)÷T, where T is the time interval when the voltage value at both ends of R12 changes from Uₜₒₜₐₗ₁ to Uₜₒₜₐₗ₂; a second calculation module, configured to calculate the estimated bus voltage value, namely calculate the change value of the bus voltage in the next time interval according to the slope, and determine the estimated bus voltage value according to the change value; a determining module, configured to determine the magnitude relationship between the estimated bus voltage value and the preset value, and the preset value including the bus high threshold value and the bus low threshold value; where when the estimated bus voltage value is greater than the bus high threshold value, the PWM modulation signal with the PWM duty cycle of upper three tubes being 0 and the PWM duty cycle of the lower three tubes being 0 is output, and slow braking is stopped; when the estimated bus voltage value is less than the bus low threshold value, the PWM modulation signal with the duty cycle of the upper three tubes being 0, and the duty cycle of the lower three tubes having the initial duty cycle and increasing slowly from the initial duty cycle, is output, and slow braking is continued. In one embodiment, the duty cycle of the upper three tubes are 0, and the lower three tubes have an initial duty cycle of 5%-50%, preferably 50%, and the duty cycle is always less than 100 % during a gradual increase. In one embodiment, the bus high threshold value is the withstand voltage value of the bus voltage. Once the withstand voltage value is exceeded, it is easy to cause damage to the MOS tube and the circuit, affecting the service life of the power tool. The bus low threshold value is the minimum threshold to ensure the braking efficiency when the brushless DC motor brakes. If it is lower than the threshold, it is easy to cause the braking time interval to be prolonged, the braking efficiency to be reduced, affecting the operating experience.

The present application also provides a mode brake control device, the device includes a memory and a processor; the memory stores computer programs that can be run on the processor, and the controller is used to execute the computer programs to implement the brake control method.

The present application also provides a computer-readable medium having a non-volatile program code executable by a processor, and the program code enables the processor to execute the brake control method.

Those skilled in the art can clearly understand that, for the convenience and brevity of description, a specific working process of the device described above can refer to the corresponding process in the aforementioned method embodiment, and will not be repeated here.

If the functions are implemented in the form of software functional units and sold or used as independent products, they can be stored in a computer-readable storage medium. Based on the understanding, a technical solution of the present application, or the part that contributes to the prior art or the part of the technical solution, can be embodied in the form of a software product. The computer software product is stored in a storage medium, including several instructions for enabling a computer device (which can be a personal computer, a server, or a network device, etc.) to perform all or part of the steps of the methods described in each embodiment of the present application. The aforementioned storage medium includes: various media that can store program codes, such as a USB flash drive, a mobile hard disk, a read-only memory (ROM), a random access memory (RAM), a magnetic disk or an optical disk.

Finally, it should be noted that the above-described embodiments are only specific implementations of the present application, which are used to illustrate the technical solutions of the present application, rather than to limit them. The protection scope of the present application is not limited thereto. Although the present application is described in detail with reference to the above-described embodiments, it should be understood by those skilled in the art that any person familiar with the technical field can still modify the technical solutions recorded in the above-described embodiments within the technical scope disclosed by the present application, or can easily think of changes, or perform equivalent replacements on some of the technical features thereof; and these modifications, changes or replacements do not make the essence of the corresponding technical solutions deviate from the spirit and scope of the technical solutions of the embodiments of the present application, and should be included in the protection scope of the present application. Therefore, the protection scope of the present application shall be subject to the protection scope of the claims.

1. A brake control method, comprising:
collecting a voltage value of a voltage-dividing resistor R₁₂;
calculating a first bus voltage value according to the voltage value of the voltage-dividing resistor R₁₂;
detecting a change of the first bus voltage value within a first time interval and calculating a voltage change rate;
estimating a second bus voltage value within a second time interval according to the voltage change rate, the second bus voltage value being an estimated bus voltage value;
determining a magnitude relationship between the estimated bus voltage value and a preset value; in response that the estimated bus voltage value is greater than or equal to the preset value, stopping a slow braking; in response that the estimated bus voltage value is less than the preset value, performing the slow braking.

2. The brake control method according to claim 1, wherein:
performing the slow braking comprises performing the slow braking according to a modulation signal with a pulse width modulation (PWM) duty cycle of upper three tubes being 0, and with a PWM duty cycle of the lower three tubes, and the PWM duty cycle of the lower three tubes having a PWM initial duty cycle and gradually increasing.

3. The braking control method according to claim 2, wherein the initial duty cycle is 5%-50%, and when performing the slow braking, the duty cycle is less than 100%.

4. The brake control method according to claim 1, wherein a bus voltage value Uₜₒₜₐₗ is calculated according to a formula of Uₜₒₜₐₗ=(R₆+R₁₂)÷R₁₂×U_{ad}, wherein U_{ad} is a voltage value of R₁₂, and R₆ is another voltage-dividing resistor.

5. The brake control method according to claim 1, wherein the voltage change rate is a slope, which is calculated according to a formula of K=(Uₜₒₜₐₗ₂−Uₜₒₜₐₗ₁)÷T, wherein K is the slope, and T is a time interval for the voltage value of R₁₂ to change from Uₜₒₜₐₗ₁ to Uₜₒₜₐₗ₂, Uₜₒₜₐₗ₁ and Uₜₒₜₐₗ₂ are voltage values of R₁₂.

6. The brake control method according to claim 1, further comprising:
in response that the estimated bus voltage value is greater than the preset value, outputting a PWM modulation signal with a PWM duty cycle of upper three tubes being 0 and a PWM duty cycle of lower three tubes being 0.

7. (canceled)

8. A brake control device, comprising:
a voltage collecting circuit configured to collect a voltage value of a voltage-dividing resistor R₁₂;
a MCU configured to calculate a first bus voltage value according to the voltage value of the voltage-dividing resistor R₁₂; detect a change of a bus voltage within a first time interval and calculate a voltage change rate; estimate a second bus voltage value; determine a magnitude relationship between the estimated bus voltage value and a preset value, and stop a slow braking in response that the estimated bus voltage value is greater than the preset value, and perform the slow braking in response that the estimated bus voltage value is less than the preset value.

9. A mode control device, comprising:
a processor;
a non-transitory storage medium, storing computer programs, which when executed by the processor, cause the processor to:
collect a voltage value of a voltage-dividing resistor R₁₂;
calculate a first bus voltage value according to the voltage value of the voltage-dividing resistor R₁₂;
detect a change of a bus voltage within a first time interval and calculate a voltage change rate;
estimate a second bus voltage value within a second time interval according to the voltage change rate, the second bus voltage value being an estimated bus voltage value;
determine a magnitude relationship between the estimated bus voltage value and a preset value;
in response that the estimated bus voltage value is greater than the preset value, stop a slow braking; and in response that the estimated bus voltage value is less than the preset value, perform the slow braking.

10. (canceled)

11. The brake control device according to claim 8, wherein the MCU performing the slow braking according to a modulation signal with a pulse width modulation (PWM) duty cycle of upper three tubes being 0, and with a PWM duty cycle of the lower three tubes, and the PWM duty cycle of the lower three tubes having a PWM initial duty cycle and gradually increasing.

12. The brake control device according to claim 11, wherein the initial duty cycle is 5%-50%, and when performing the slow braking, the duty cycle is less than 100%.

13. The brake control device according to claim 8, wherein the MCU calculates a bus voltage value Uₜₒₜₐₗ according to a formula of Uₜₒₜₐₗ=(R₆+R₁₂)÷R₁₂×U_{ad}, wherein U_{ad} is a voltage value of R₁₂, and R₆ is another voltage-dividing resistor.

14. The brake control device according to claim 8, wherein the voltage change rate is a slope, the MCU calculates the voltage change rate according to a formula of K=(Uₜₒₜₐₗ₂−Uₜₒₜₐₗ₁)÷T, wherein K is the slope, and T is a time interval for the voltage value of R₁₂ to change from Uₜₒₜₐₗ₁ to Uₜₒₜₐₗ₂, Uₜₒₜₐₗ₁ and Uₜₒₜₐₗ₂ are voltage values of R₁₂.

15. The brake control device according to claim 8, wherein in response that the estimated bus voltage value is greater than the preset value, the MCU outputs a PWM modulation signal with a PWM duty cycle of upper three tubes being 0 and a PWM duty cycle of lower three tubes being 0.

16. The brake control device according to claim 8, wherein the preset value comprises a withstand voltage value of the bus voltage.

17. The mode control device according to claim 9, wherein the processor performs the slow braking according to a modulation signal with a pulse width modulation (PWM) duty cycle of upper three tubes being 0, and with a PWM duty cycle of the lower three tubes, and the PWM duty cycle of the lower three tubes having a PWM initial duty cycle and gradually increasing.

18. The mode control device according to claim 16, wherein the initial duty cycle is 5%-50%, and when performing the slow braking, the duty cycle is less than 100%.

19. The mode control device according to claim 9, wherein the processor calculates a bus voltage value Uₜₒₜₐₗ according to a formula of Uₜₒₜₐₗ=(R₆+R₁₂)÷R₁₂×U_{ad}, wherein U_{ad} is a voltage value of R₁₂, and R₆ is another voltage-dividing resistor.

20. The mode control device according to claim 9, wherein the voltage change rate is a slope, the processor calculates the voltage change rate according to a formula of K=(Uₜₒₜₐₗ₂−Uₜₒₜₐₗ₁)÷T, wherein K is the slope, and T is a time interval for the voltage value of R₁₂ to change from Uₜₒₜₐₗ₁ to Uₜₒₜₐₗ₂, Uₜₒₜₐₗ₁ and Uₜₒₜₐₗ₂ are voltage values of R₁₂.

21. The mode control device according to claim 9, wherein in response that the estimated bus voltage value is greater than the preset value, the processor outputs a PWM modulation signal with a PWM duty cycle of upper three tubes being 0 and a PWM duty cycle of lower three tubes being 0.

22. The mode control device according to claim 9, wherein the preset value comprises a withstand voltage value of the bus voltage.
